(19) United States
(12) Patent Application Publication
(10) Pub. No.: US 2015/0194326 A1
(43) Pub. Date: Jul. 9, 2015

(54) PECVD CERAMIC HEATER WITH WIDE RANGE OF OPERATING TEMPERATURES

(71) Applicant: Applied Materials, Inc., Santa Clara, CA (US)

(72) Inventors: Jianhua ZHOU, Campbell, CA (US); Juan Carlos Rocha-Alvarez, San Carlos, CA (US)

(73) Assignee: Applied Materials, Inc., Santa Clara, CA (US)

(21) Appl. No.: 14/149,070

(22) Filed: Jan. 7, 2014

(51) Int. Cl. H01L 21/67; H01L 21/687

(52) U.S. Cl. CPC H01L 21/67103; H01L 21/68792

(57) ABSTRACT

Embodiments of the present invention generally relate to semiconductor processing chamber, and more specifically, a heated support pedestal for a semiconductor processing chamber. In one embodiment, the pedestal comprises a substrate support including a support surface for receiving a substrate, a heating element encapsulated within the substrate support, and a first hollow shaft having a first end and a second end, where the first end is fixed to the substrate support. The substrate support and the first hollow shaft are made of a ceramic material and the first hollow shaft has a length between about 50 mm to 100 mm. The pedestal further comprises a second hollow shaft coupled to the second end of the first hollow shaft. The second hollow shaft has a length that is greater than the length of the first hollow shaft.

### BACKGROUND

1. Field

Embodiments of the present invention generally relate to semiconductor processing chamber, and more specifically, a heated support pedestal for a semiconductor processing chamber.

2. Description of the Related Art

Semiconductor processing involves a number of different chemical and physical processes whereby minute integrated circuits are created on a substrate. Layers of materials which make up the integrated circuit are created by processes including chemical vapor deposition, physical vapor deposition, epitaxial growth, and the like. Some of the layers of material are patterned using photoresist masks and wet or dry etching techniques. The substrates utilized to form integrated circuits may be silicon, gallium arsenide, indium phosphide, glass, or other appropriate materials.

In the manufacture of integrated circuits, plasma processes are often used for deposition or etching of various material layers. Plasma processing offers many advantages over thermal processing. For example, plasma enhanced chemical vapor deposition (PECVD) allows deposition processes to be performed at lower temperatures and at higher deposition rates than achievable in analogous thermal processes. Thus, PECVD is advantageous for integrated circuit fabrication with stringent thermal budgets, such as for very large scale or ultra-large scale integrated circuit (VLSI or ULSI) device fabrication.

The processing chambers used in these processes typically include a substrate support or pedestal disposed therein to support the substrate during processing. In some processes, the pedestal may include an embedded heater adapted to control the temperature of the substrate and/or provide elevated temperatures that may be used in the process. Proper temperature control and uniform heating of the substrate during substrate processing is very important, particularly as the size of integrated circuits decreases. Conventional supports with embedded heaters often have numerous hot and cold spots which affect the quality of films deposited on the substrate.

Therefore, there is a need for a pedestal that provides active temperature control at all times throughout a complete process cycle.

### SUMMARY

Embodiments of the present invention generally relate to semiconductor processing chamber, and more specifically, a heated support pedestal for a semiconductor processing chamber. In one embodiment, the pedestal comprises a substrate support including a support surface for receiving a substrate, a heating element encapsulated within the substrate support, and a first hollow shaft having a first end and a second end, where the first end is fixed to the substrate support. The substrate support and the first hollow shaft are made of a ceramic material and the first hollow shaft has a first length. The pedestal further comprises a second hollow shaft coupled to the second end of the first hollow shaft. The second hollow shaft is made of a metal and has cooling channels disposed within the shaft. The second hollow shaft has a second length that is about 1.5 to 10 times greater than the first length. The pedestal further comprises a RF rod disposed within the first hollow shaft and the second hollow shaft.

In another embodiment, a pedestal for a semiconductor processing chamber is disclosed. The pedestal comprises a substrate support including a support surface for receiving a substrate, a heating element encapsulated within the substrate support, a first hollow shaft fixed to the substrate support, where the substrate support and the first hollow shaft are made of a ceramic material and the first hollow shaft has a length between 50 mm and 100 mm, a second hollow shaft coupled to the first hollow shaft, where the second hollow shaft is made of a metal and has a length between 150 mm and 500 mm, and a RF rod disposed within the first hollow shaft and the second hollow shaft.

In another embodiment, a plasma processing chamber is disclosed. The plasma processing chamber comprises a chamber body including a processing region. The plasma processing chamber further comprises a pedestal disposed in the processing region, where the pedestal comprises a substrate support including a support surface for receiving a substrate, a heating element encapsulated within the substrate support, and a first hollow shaft having a first end and a second end, where the first end is fixed to the substrate support. The substrate support and the first hollow shaft are made of a ceramic material and the first hollow shaft has a length between about 50 mm to 100 mm. The plasma processing chamber further comprises a second hollow shaft coupled to the second end of the first hollow shaft. The second hollow shaft is made of a metal and has cooling channels disposed within the shaft. The second hollow shaft has a length that is greater than the length of the first hollow shaft. The plasma processing chamber further comprises a RF rod disposed within the first hollow shaft and the second hollow shaft.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a plasma processing chamber according to one embodiment.

FIG. 2 is a schematic sectional view of a pedestal according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to semiconductor processing chamber, and more specifically, a heated support pedestal for a semiconductor processing chamber. In one embodiment, the pedestal comprises a substrate support including a support surface for receiving a substrate, a heating element encapsulated within the substrate support, and a first hollow shaft having a first end and a second end, where the first end is fixed to the substrate support. The substrate support and the first hollow shaft are made of a ceramic material and the first hollow shaft has a length between about 50 mm to 100 mm. The pedestal further comprises a second hollow shaft coupled to the second end of the first hollow shaft. The second hollow shaft has a length that is greater than the length of the first hollow shaft.

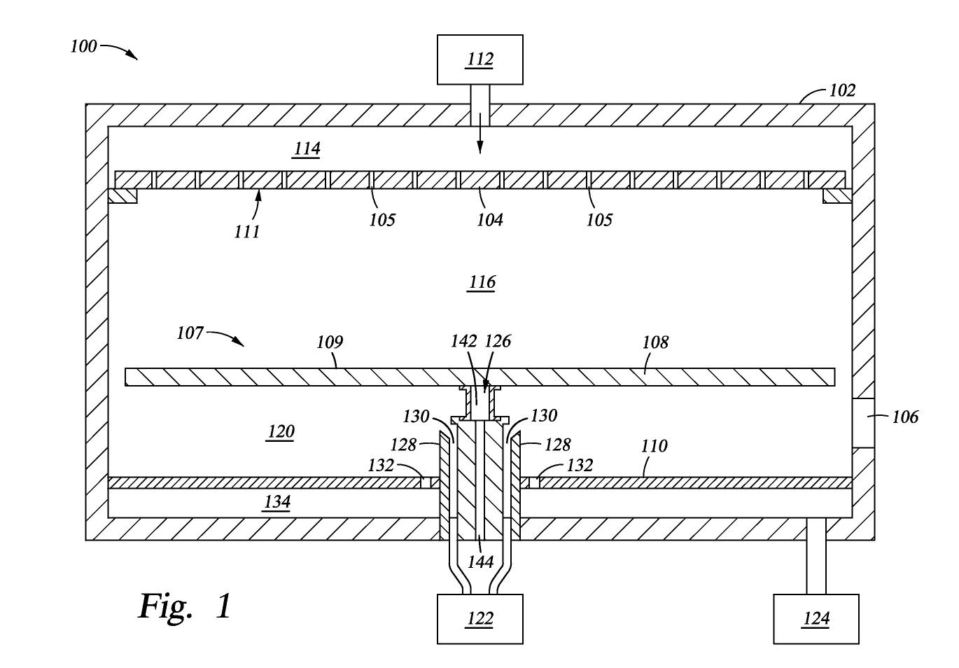

FIG. 1 is a schematic sectional view of a plasma processing chamber 100 according to one embodiment of the present invention. The plasma processing chamber 100 includes a chamber body 102. Within the chamber body 102, a gas distribution showerhead 104 is present that has a plurality of openings 105 therethrough to permit processing gas from a gas source 112 to pass through the showerhead 104 into a processing space 116.

Substrates are inserted into and removed from the chamber body 102 through a slit valve opening 106 formed through the chamber body 102.

A pedestal 107 is disposed in the chamber body 102. The pedestal 107 includes a substrate support 108 and a stem 126. The substrate support 108 may be substantially flat having a support surface 109 for supporting the substrate thereon. The support surface 109 faces a lower surface 111 of the gas distribution showerhead 104 and may be substantially parallel to the gas distribution showerhead 104. The substrate support 108 may be substantially circular, rectangular, squared, or of other shape depending on the shape of the substrate being processed. The substrate support 108 may be formed of ceramics, or other non-electrically conductive material capable of withstanding the plasma environment in the chamber body 102. In one embodiment, the substrate support 108 may be a unitary monolith structure composed of aluminum nitride or aluminum oxide. The substrate support is disposed on the stem 126, and the stem 126 includes a first shaft 142 and a second shaft 144 (described in detail below).

Below the substrate support 108 is a second plate 110 that is spaced from the substrate support 108 by an evacuation plenum 120. A sleeve 128 is disposed between the stem 126 and the plate 110, and a gap 130 is formed between the sleeve 128 and the stem 126. A purging gas may be introduced from a purge gas source 122, flowed through the gap 130 into the evacuation plenum 120. As the purging gas flows through the gap 130, the sealing components such as vacuum seal o-rings disposed between the first shaft 142 and the second shaft 144 are protected from chemical attacks. The purge gas in the evacuation plenum 120, along with processing gas, may flow into a bottom plenum 134 through an opening 132 formed in the plate 110 and out of the chamber body 120 through the vacuum pump 124. In one embodiment, the flow rate of the purging gas is about 5 sccm to about 200 sccm.

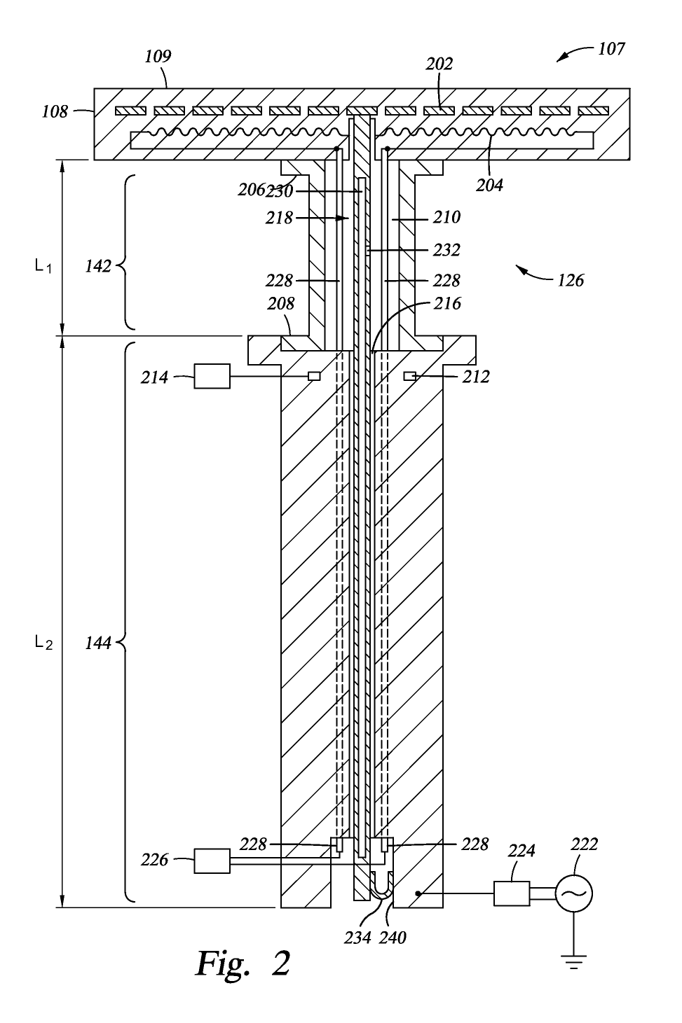

FIG. 2 is a schematic sectional view of the pedestal 107 according to one embodiment. As shown in FIG. 2, the substrate support 108 is fixed to the first shaft 142, and the first shaft 142 is coupled to the second shaft 144 at an end opposite the substrate support 108. The substrate support 108 includes an RF electrode 202 for generating a plasma between the substrate support 108 and the gas distribution showerhead 104. The RF electrode 202 may be formed from a metallic material and may be embedded in the substrate support 108. The substrate support 108 may also include a heating element 204 to heat the substrate disposed on the support surface 109. In one embodiment, the heating element 204 includes multiple heating elements such as multi-zone heaters. During operation, the temperature of the substrate disposed on the substrate support 108 may be between about 150 degrees Celsius and 650 degrees Celsius. To provide the ability to actively control the temperature of the substrate over a wider temperature range, the second shaft 142, which contains cooling channels, is placed as close to the substrate support 108 as possible. In addition, heat loss through the first shaft 142 and the second shaft 144 is increased and is controllable by varying the coolant temperature and flow rate inside the cooling channels.

The first shaft 142 has a first end 206 that is fixed to the substrate support 108 and a second end 208 that is coupled to the second shaft 144. The first shaft 142 may be made of a ceramic material such as aluminum nitride, silicon carbide or silicon oxide, and may be made of the same material as the substrate support 108. If the first shaft 142 and the substrate support 108 are made of the same material, such as aluminum nitride, the first shaft 142 and the substrate support 108 may have a strong bond as a result of diffusion bonding. To decrease the distance between the substrate support 108 and the second shaft 144, the first shaft 142 has a length “L1” that ranges from about 50 millimeters (mm) to about 100 mm. The first shaft 142 is hollow and has an inner opening 210 to accommodate electrical connections to the RF electrode 202 and the heating element 204.

The second shaft 144 is coupled to the second end 208 of the first shaft 142. The second shaft 144 has a greater length “L2” than the length “L1” of the first shaft 142. In one embodiment, the length “L2” is about 1.5 to 10 times greater than the length “L1”, such as about 3 to 5 times greater than the length “L1”. In one embodiment, the second shaft 144 has a length “L2” of about 150 mm to 500 mm, such as about 300 mm. The second shaft 144 may have a greater outer diameter than the outer diameter of the first shaft 142. The second shaft 144 may be made of a metal such as aluminum and includes cooling channels 212 disposed therein. The cooling channels 212 may be as close to the interface between the first shaft 142 and the second shaft 144 as possible, because the vacuum seal o-rings disposed between the first shaft 142 and the second shaft 144 may not withstand elevated temperatures of the substrate support 108 such as greater than 500 degrees Celsius. The channels 212 are connected to a coolant source 214. The coolant is utilized to flow inside the channels 212 of the second shaft 144 may be any suitable coolant, such as water at a temperature ranging from about 10 degrees Celsius to 80 degrees Celsius. The second shaft 144 is hollow and has an inner opening 216 to accommodate electrical connections to the RF electrode 202.

The RF electrode 202 is coupled to a RF connector assembly 218 disposed in the inner opening 210 of the first shaft 142 and the inner opening 216 of the second shaft 144. The RF connector assembly 218 extends through the shafts 142, 144 and may be connected to a RF power source 222 through a matching network 224. The RF power source 222 may be connected through the matching network 224 to one or more chamber components in the processing chamber 100 for generating plasma within the processing chamber 100. The RF power source 222 is capable of providing RF power of from about 100 watts to about 5000 watts to the RF electrode 202 and the one or more chamber components.

The RF connector assembly 218 includes an RF conducting rod 230 and a flexible strap 234. The RF conducting rod 230 may be hollow and have a diameter from about 3 mm to about 8 mm. A venting hole 232 may be formed in the RF conducting rod 230. The RF conducting rod 230 is directly coupled to the RF electrode 202 at one end and the flexible strap 234 at the other end. The flexible strap 234 is coupled between the RF conduction rod 230 and an inner surface of the second shaft 144. The flexible strap 234 may be directed mounted to the end of the RF electrode 202 or mounted to the end of the RF electrode 202 by a RF clamp (not shown). The second shaft 144 may be further connected to the matching network 224. Thus, the RF electrode 202 may be RF grounded or RF powered by the RF power source 222 through the connection of the matching network 224, the second shaft 144, the flexible strap 234 and the RF conducting rod 230.

The heating element 204 may be connected to a power source 226 through terminal rods 228 disposed in and extending along the inner opening 210 of the first shaft 142. A portion of the terminal rods 228 may be embedded in the second shaft 144, as shown in FIG. 2. The power source 226 may provide a DC voltage to power the heating element 204. In one embodiment, the power source 226 may be capable of delivering from about 100 to about 4000 Watts of direct current to the heating element 204.

The heating element 204 may be a resistive heater, such as an electrical resistor wire that generates heat upon application of a voltage across the wire. For example, the heating element 204 may be a metal wire having a cylindrical cross-section that is coiled concentrically to form a spiral from the center to the edge of substrate support 108. A suitable metal wire may be a molybdenum or nichrome wire.

While the foregoing is directed to embodiments of the present invention, other and further embodiments of the invention may be devised without departing from the basic scope thereof, and the scope thereof is determined by the claims that follow.

1. A pedestal for a semiconductor processing chamber, comprising:
a substrate support including a support surface for receiving a substrate;
a heating element encapsulated within the substrate support;
a first hollow shaft having a first end and a second end, wherein the first end is fixed to the substrate support, wherein the substrate support and the first hollow shaft are made of a ceramic material and the first hollow shaft has a first length;
a second hollow shaft coupled to the second end of the first hollow shaft, wherein the second hollow shaft is made of a metal and has cooling channels disposed within the second hollow shaft, and wherein the second hollow shaft has a second length that is about 1.5 to 10 times greater than the first length; and
a RF conducting rod disposed within the first hollow shaft and the second hollow shaft.

2. The pedestal of claim 1, wherein the first hollow shaft is made of a same material as the substrate support, the first length is about 50 mm to 100 mm, and the second length is about 3 to 5 times greater than the first length.

3. The pedestal of claim 2, wherein the first hollow shaft is made of aluminum nitride.

4. The pedestal of claim 3, wherein the second hollow shaft is made of aluminum.

5. The pedestal of claim 1, wherein the length of the second hollow shaft ranges from about 150 mm to about 500 mm.

6. The pedestal of claim 1, wherein the RF conducting rod is hollow.

7. The pedestal of claim 6, wherein the RF conducting rod and has a diameter ranging from about 3 mm to about 8 mm.

8. A pedestal for a semiconductor processing chamber, comprising:
a substrate support including a support surface for receiving a substrate;
a heating element encapsulated within the substrate support;
a first hollow shaft fixed to the substrate support, wherein the substrate support and the first hollow shaft are made of a ceramic material and the first hollow shaft has a length between 50 mm and 100 mm;
a second hollow shaft coupled to the first hollow shaft, wherein the second hollow shaft is made of a metal and has a length between 150 mm and 500 mm; and
a RF rod disposed within the first hollow shaft and the second hollow shaft.

9. The pedestal of claim 8, wherein the first hollow shaft is made of a same material as the substrate support.

10. The pedestal of claim 9, wherein the first hollow shaft is made of aluminum nitride.

11. The pedestal of claim 10, wherein the second hollow shaft is made of aluminum.

12. The pedestal of claim 8, wherein the second hollow shaft has cooling channels disposed within the second hollow shaft.

13. The pedestal of claim 8, wherein the RF conducting rod is hollow.

14. The pedestal of claim 13, wherein the RF conducting rod has a diameter ranging from about 3 mm to about 8 mm.

15. A plasma processing chamber, comprising:
a chamber body having a processing region; and
a pedestal disposed in the processing region, wherein the pedestal comprises:
a substrate support including a support surface for receiving a substrate;
a heating element encapsulated within the substrate support;
a first hollow shaft having a first end and a second end, wherein the first end is fixed to the substrate support, wherein the substrate support and the first hollow shaft are made of a ceramic material and the first hollow shaft has a length between about 50 mm to 100 mm;
a second hollow shaft coupled to the second end of the first hollow shaft, wherein the second hollow shaft is made of a metal and has cooling channels disposed within the second hollow shaft, and wherein the second hollow shaft has a length that is greater than the length of the first hollow shaft; and
a RF rod disposed within the first hollow shaft and the second hollow shaft.

16. The pedestal of claim 15, wherein the first hollow shaft is made of a same material as the substrate support.

17. The pedestal of claim 16, wherein the first hollow shaft is made of aluminum nitride.

18. The pedestal of claim 17, wherein the second hollow shaft is made of aluminum.

19. The pedestal of claim 15, wherein the length of the second hollow shaft ranges from about 150 mm to about 500 mm.

20. The pedestal of claim 15, wherein the RF conducting rod is hollow and has a diameter ranging from about 3 mm to about 8 mm.
